(19) United States
(12) Patent Application Publication
(10) Pub. No.: US 2013/0104954 A1
(43) Pub. Date: May 2, 2013

(54) EMBEDDED BYPASS DIODES DESIGN IN PHOTOVOLTAIC DEVICE AND METHOD OF MANUFACTURING THE SAME

(71) Applicants: Yang-Yang ZHOU, Hong Kong (HK); Hsieh-Hsin Yeh, New Taipei City (TW); Jia-Wei Ma, New Taipei City (TW)

(72) Inventors: Yang-Yang ZHOU, Hong Kong (HK); Hsieh-Hsin Yeh, New Taipei City (TW); Jia-Wei Ma, New Taipei City (TW)

(73) Assignee: Du Pont Apollo Limited, Hong Kong (HK)

(21) Appl. No.: 13/284,947

(22) Filed: Oct. 30, 2011

(51) Int. Cl. H01L 31/05; H01L 31/18

(52) U.S. Cl. 136/244; 438/98; 257/E31.126

(57) ABSTRACT

A photovoltaic device is disclosed, which includes a transparent substrate, a set of photovoltaic cells and at least one bypass diode device. The photovoltaic cells are connected to each other in series and include a plurality of front electrode segments formed on the transparent substrate, a plurality of photoelectric conversion segments of semiconductor material formed on the front electrode segments, and a plurality of first back electrode segments of metal formed on the photoelectric conversion segments respectively. The bypass diode device is formed on the transparent substrate and substantially equal in layer construction to each of the photovoltaic cells, where the bypass diode and the photovoltaic cells share two or more of the front electrode segments.

### BACKGROUND

1. Technical Field

The present disclosure relates to a photoelectric device, and more particularly, a photovoltaic device for solving the hot-spot problem with thin-film solar cells.

2. Description of Related Art

Energy is the source power of all economic activities and thus is highly relative to the economic advancement. For the time being, energy sources include fossil energies such as petroleum, natural gas, and coal, nuclear power, waterpower, terrestrial heat and solar energy. Among the above-mentioned energy sources, fossil energies are the most widely used energy with nuclear, power being in second place, whereas the others are much less commonly used. However, upon combustion, fossil energies produce greenhouse gas such as carbon dioxides, nitrogen oxides, sulfur oxides, and hydrocarbons that are detrimental to the environment. Hence, how to reduce greenhouse gas emission has become a major international issue.

A solar cell is a device that converts the energy of sunlight directly into electricity by the photovoltaic effect. Sometimes the term solar cell is reserved for devices intended specifically to capture energy from sunlight, while the term photovoltaic cell is used when the light source is unspecified. Assemblies of cells are used to make solar panels, solar modules, or photovoltaic arrays. Photovoltaic is the field of technology and research related to the application of solar cells in producing electricity for practical use. The energy generated this way is an example of solar energy. FIG. 1 is a top view and a cross view for illustrating a conventional photovoltaic device. This conventional photovoltaic device is disposed on a transparent substrate 110, in which P1 represents removal of the front contact layer 021 (e.g., TCO layer), P2 represents removal of the photoelectric conversion layer 023 (i.e., semiconductor layer), and P3 represents removal of the layers 023 and back-electrode layer 025 (i.e., metal & semiconductor layers). Moreover, ribbons 080 are disposed at two opposing sides of the photovoltaic device.

Hot-spot test is a very important reliability test for solar cells [IEC 61646-1]. To reduce the failure of hot-spot test significantly, comparable number of parallel-connected bypass diodes are needed. These bypass diodes are always connected externally and are complicated to be realized. Parallel connected bypass diodes are always used to eliminate the hot-spot effect of solar cells and now most of the bypass diodes are external. Examples are given in U.S. Pat. No. 6,288,323. To reduce the hot-spot effect of solar cell modules significantly, comparable number of bypass diodes are needed, which is hard to be complimented. In this patent, the bypass diodes can be fabricated within the same solar cell module and parallel-connected to the active solar cells internally.

### SUMMARY

The following presents a simplified summary of the disclosure in order to provide a basic understanding to the reader. This summary is not an extensive overview of the disclosure and it does not identify key/critical elements of the present invention or delineate the scope of the present invention. Its sole purpose is to present some concepts disclosed herein in a simplified form as a prelude to the more detailed description that is presented later.

According to one embodiment of the present invention, a photovoltaic device includes a transparent substrate, a set of photovoltaic cells and at least one bypass diode device. The photovoltaic cells are connected to each other in series and include a plurality of front electrode segments formed on the transparent substrate, a plurality of photoelectric conversion segments of semiconductor material formed on the front electrode segments, and a plurality of first back electrode segments of metal formed on the photoelectric conversion segments respectively. The bypass diode device is formed on the transparent substrate and substantially equal in layer construction to each of the photovoltaic cells, where the bypass diode device and the photovoltaic cells share two or more of the front electrode segments.

According to another embodiment of the present invention, a method of manufacturing a photovoltaic device includes following steps: providing a transparent substrate; depositing a transparent conductive oxide film on a transparent substrate to form a front contact layer; forming first grooves in the front contact layer to form front electrode segments on the transparent substrate; depositing and forming a layer or layers of a semiconductor material on the front electrode segments, and filling the first grooves with the semiconductor material; forming second grooves and one or more third grooves in the layer or layers of semiconductor material at positions substantially parallel to the first grooves, wherein the second and third grooves are staggered in two adjacent regions of the layer or layers of semiconductor material; depositing and forming a back contact layer comprising a metal on the layer or layers of semiconductor material, and filling the second and third grooves with the metal to form a series connection to connect the front electrode segments and the back contact layer; forming fourth grooves in the back contact layer and the layer or layers of semiconductor material at positions substantially parallel to the second grooves; forming a separation groove in the back contact layer and the layer or layers of semiconductor material at a direction which crosses the direction of the second and third grooves, so that the two adjacent regions of the layer or layers of semiconductor material are separated by the separation groove.

Many of the attendant features will be more readily appreciated, as the same becomes better understood by reference to the following detailed description considered in connection with the accompanying drawings.

### BRIEF DESCRIPTION OF THE DRAWINGS

The present description will be better understood from the following detailed description read in light of the accompanying drawing, wherein:

FIG. 1 is a top view and a cross view for illustrating a conventional photovoltaic device;

FIG. 2 is a schematic diagram illustrating a photovoltaic device according to one or more embodiments of the present invention;

FIG. 3 is a schematic diagram of a photovoltaic cell parallel connected by a bypass diode of FIG. 2;

FIG. 4 is an equivalent circuit diagram of the photovoltaic device of FIG. 2;

FIG. 5 is a top view and a cross view for illustrating a photovoltaic device according to one or more embodiments of the present invention;

FIG. 6 shows that the bypass diodes of FIG. 5 are covered with a mask during normal operation;

FIG. 7 is a light I-V curve before the reverse current overload of a bypass diode of FIG. 2 according to one or more embodiments of the present invention;

FIG. 8 is another dark I-V curve according to one or more embodiments of the present invention; and

FIG. 9 is a schematic diagram illustrating another photovoltaic device according to one or more embodiments of the present invention.

### DETAILED DESCRIPTION

In the following detailed description, for purposes of explanation, numerous specific details are set forth in order to attain a thorough understanding of the disclosed embodiments. It will be apparent, however, that one or more embodiments may be practiced without these specific details. In other instances, well-known structures and devices are schematically shown in order to simplify the drawing.

As used in the description herein and throughout the claims that follow, the meaning of “a”, “an”, and “the” includes reference to the plural unless the context clearly dictates otherwise. Also, as used in the description herein and throughout the claims that follow, the terms “comprise or comprising”, “include or including”, “have or having”, “contain or containing” and the like are to be understood to be open-ended, i.e., to mean including but not limited to. As used in the description herein and throughout the claims that follow, the meaning of “in” includes “in” and “on” unless the context clearly dictates otherwise.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

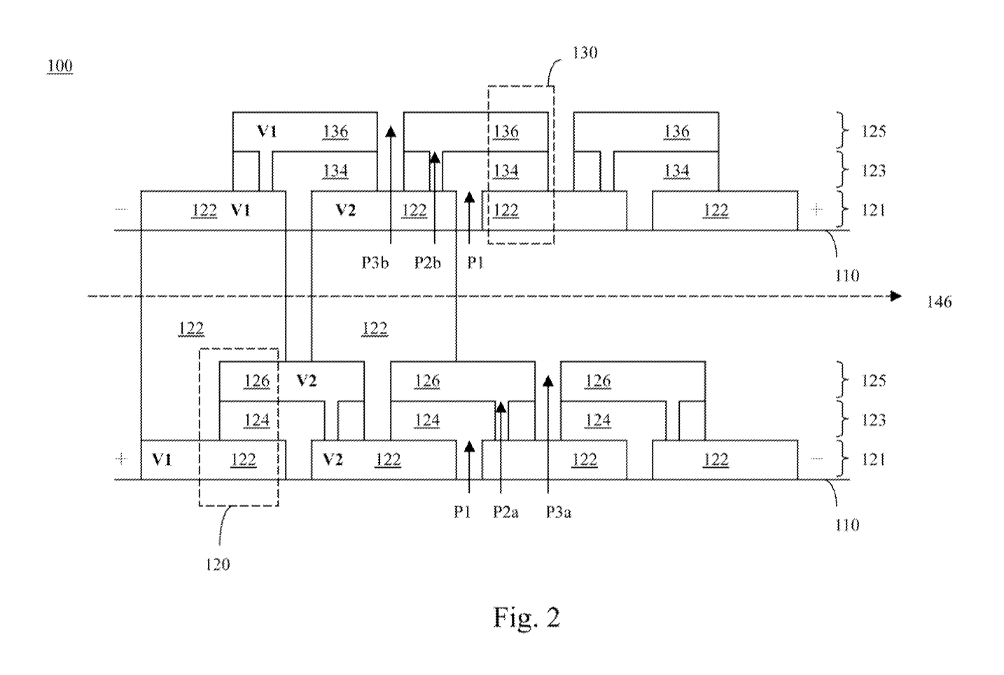

FIG. 2 is a schematic diagram illustrating a photovoltaic device 100 according to one or more embodiments of the present invention. The photovoltaic device 100 includes a transparent substrate 110, a set of photovoltaic cells 120 and at least one bypass diode device that is composed of series-connected bypass diodes 130. The photovoltaic cells 120 connected to each other in series are formed on a transparent substrate 110, e.g., glass, and subjected to solar radiation or other light passing through transparent substrate 110, and the photovoltaic cells 120 can convert light energy into electrical energy.

The photovoltaic cells 120 include a plurality of front electrode segments 122 of transparent conductive oxide formed on the transparent substrate 110, a plurality of photoelectric conversion segments 124 of semiconductor material, such as, for example, hydrogenated amorphous silicon, formed on the front electrode segments 122, and a plurality of first back electrode segments 126 of metal, such as aluminum, formed on the photoelectric conversion segments 124 respectively. Each of the photoelectric conversion segments 124 can comprise, for example, a PIN structure. In use, the front electrode segments 122 can serve as cathodes, and the first back electrode segments 126 can serve as anodes.

The bypass diode device composed of the series-connected bypass diodes 130 is formed on the transparent substrate 110 and substantially equal in layer construction to each of the photovoltaic cells 120, where the bypass diode 130 and the photovoltaic cells 120 share two or more of the front electrode segments.

The front electrode segments 122 are separated by first grooves P1, each of the photoelectric conversion segments 124 is formed on adjacent two of front electrode segments 122, and the first grooves P1 are filled with the semiconductor material.

The bypass diode device is composed of a set of bypass diodes 130 that are connected to each other in series and includes a plurality of semiconductor segments 134 of the semiconductor material formed on the front electrode segments and being parallel to the photoelectric conversion segments 124, and a plurality of second back electrode segments 136 of the metal formed on the semiconductor segments 134 respectively and being parallel to the first back electrode segments 124. In use, the front electrode segments 122 can serve as cathodes, and the second back electrode segments 136 can serve as anodes.

Each of the semiconductor segments 134 is formed on adjacent two of front electrode segments 122. Each of the photoelectric conversion segments 124 has a second grooves P2a located at one of the adjacent two of front electrode segments 122; each of the semiconductor segments 134 has a third groove P2b located at the other of the adjacent two of front electrode segments 122. The second grooves P2a are filled with the metal to form a series connection to connect the front electrode segments 122 and the first back electrode segments 126; the third grooves P2b are filled with the metal to form a series connection to connect the front electrode segments 122 and the second back electrode segments 136.

The first back electrode segments 126 are separated by fourth grooves P3a, and the photoelectric conversion segments 124 are also separated by the fourth grooves P3a.

The second back electrode segments 136 are separated by fifth grooves P3b, and the semiconductor segments 134 are also separated by the fifth grooves P3b.

A group of the first back electrode segments 126 and another group of the second back electrode segments 126 are separated by a separation groove 146 at a direction that crosses the direction of the first grooves P1, where the separation groove 146 is an isolation without TCO cut. Additionally or alternatively, a group of the photoelectric conversion segments 124 and another group of the semiconductor segments 134 are separated by the separation groove 146.

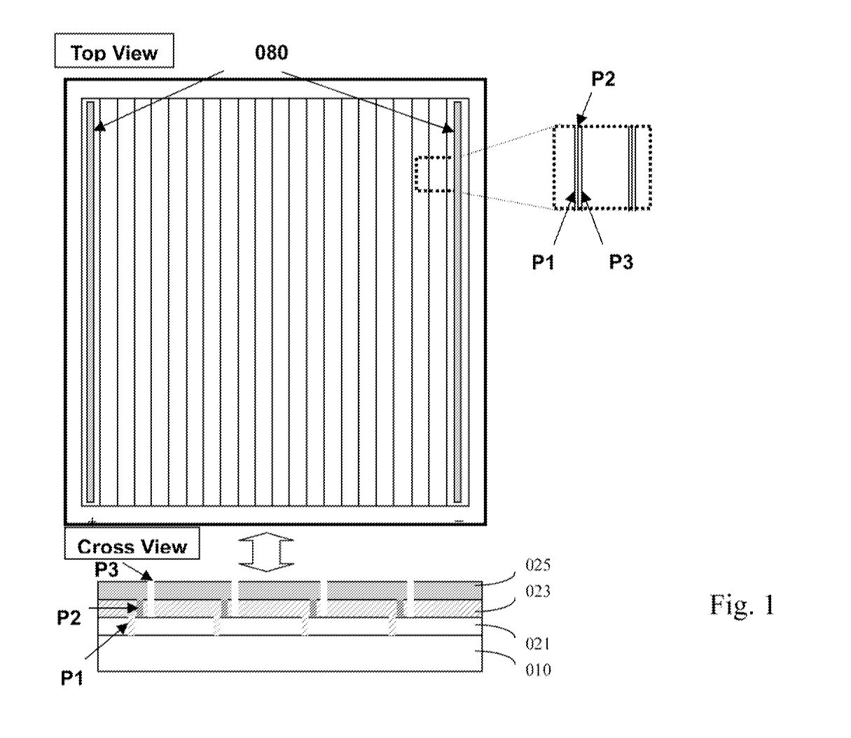

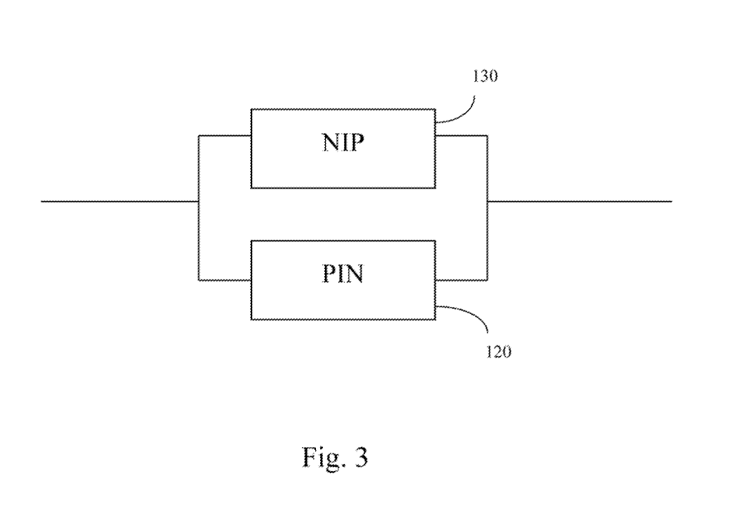

FIG. 3 is a schematic diagram of the photovoltaic cell 120 and a bypass diode 130. The photovoltaic cell 120 has a PIN structure. The bypass diode 130 has a NIP structure. As shown in FIGS. 1-2, the bypass diode 130 is parallel connected with the photovoltaic cell 120. (The bypass diodes will be covered as only their diode characteristics will be used.)

For a more complete understanding of a fabrication process of the photovoltaic device 100, referring to FIG. 2. A method of manufacturing the photovoltaic device 100 includes following steps: providing a transparent substrate 110; depositing a transparent conductive oxide film on a transparent substrate 110 to form a front contact layer 121; forming first grooves P1 in the front contact layer 121 to form front electrode segments 122 on the transparent substrate 110; depositing and forming a layer or layers 123 of a semiconductor material on the front electrode segments 122, and filling the first grooves P1 with the semiconductor material; forming the second and third grooves P2a and P2b in the layer or layers 123 of semiconductor material at positions substantially parallel to the first grooves P1, wherein the second and third grooves P2a and P2b are staggered in two adjacent regions of the layer or layers 123 of semiconductor material; depositing and forming a back contact layer 125 comprising a metal on the layer or layers 123 of semiconductor material, and filling the second and third grooves P2a and P2b with the metal to form a series connection to connect the front electrode segments 122 and the back contact layer 125; forming fourth grooves P3a in the back contact layer 125 and the layer or layers 123 of semiconductor material at positions substantially parallel to the second grooves P2a, so as to from photoelectric conversion segments 124 of semiconductor material and the first back electrode segments 126 of metal thereon; forming a separation groove 146 in the back contact layer 125 and the layer or layers 123 of semiconductor material at a direction which crosses the direction of the second and third grooves P2a and P2b, so that the two adjacent regions of the layer or layers of semiconductor material are separated by the separation groove 146.

The method of manufacturing the photovoltaic device 100 may also include the step of forming fifth grooves P3b in the back contact layer 125 and the layer or layers 123 of semiconductor material at positions substantially parallel to the second grooves P2a, so as to from semiconductor segments 134 of semiconductor material and the second back electrode segments 136 of metal thereon.

The step of forming any of above-mentioned grooves includes laser scribing or chemical etching any of these grooves.

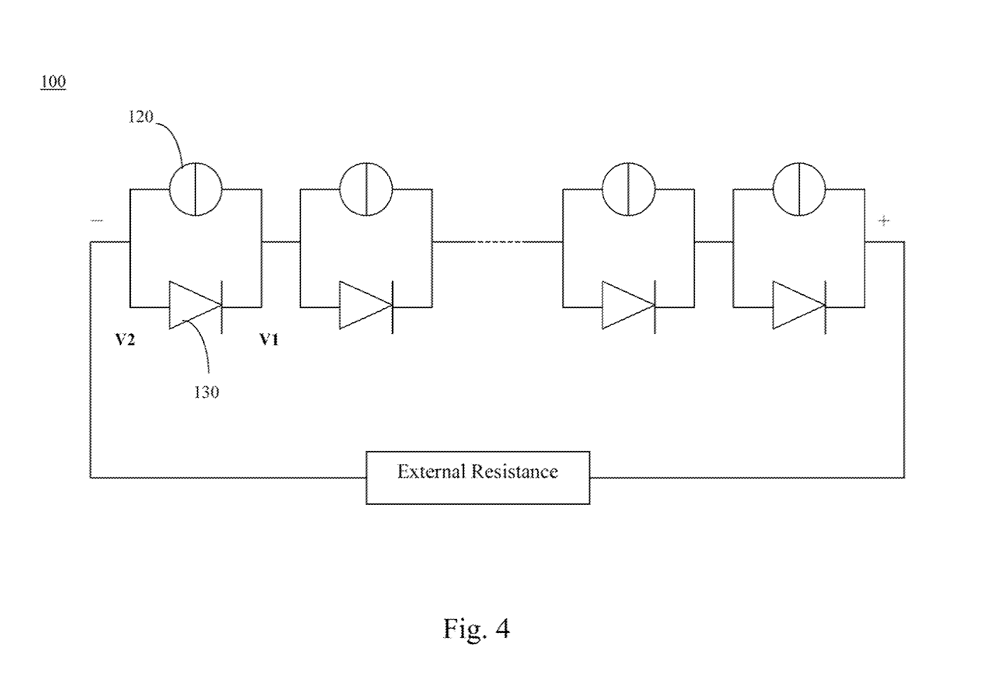

FIG. 4 is an equivalent circuit diagram of the photovoltaic device 100. The bypass diode 130 is parallel connected with the photovoltaic cells 120. During normal operation of the photovoltaic device 100, the bypass diodes 130 need to be covered to prevent light exposure and photocurrent leakage. Then, there will be a −Voc (˜0.82 V) applied to the bypass diode, which is much smaller than its breakdown reverse voltage (>−2 V) (See FIGS. 3 and 4), indicating that the dark leakage current from the bypass diode can be neglected. If the photovoltaic cell 120 is shaded, i.e., in the hot-spot condition, the corresponding bypass diode 130 will be forward-biased and works with a reverse current of module Isc. According to the area ratio of the photovoltaic cell 120 to the bypass diode 130, this Isc may be up to 10 times the Isc that the bypass diode 130 can generate itself. Therefore, there is a need to test whether the bypass diode 130 can stand such large module Isc for a long time.

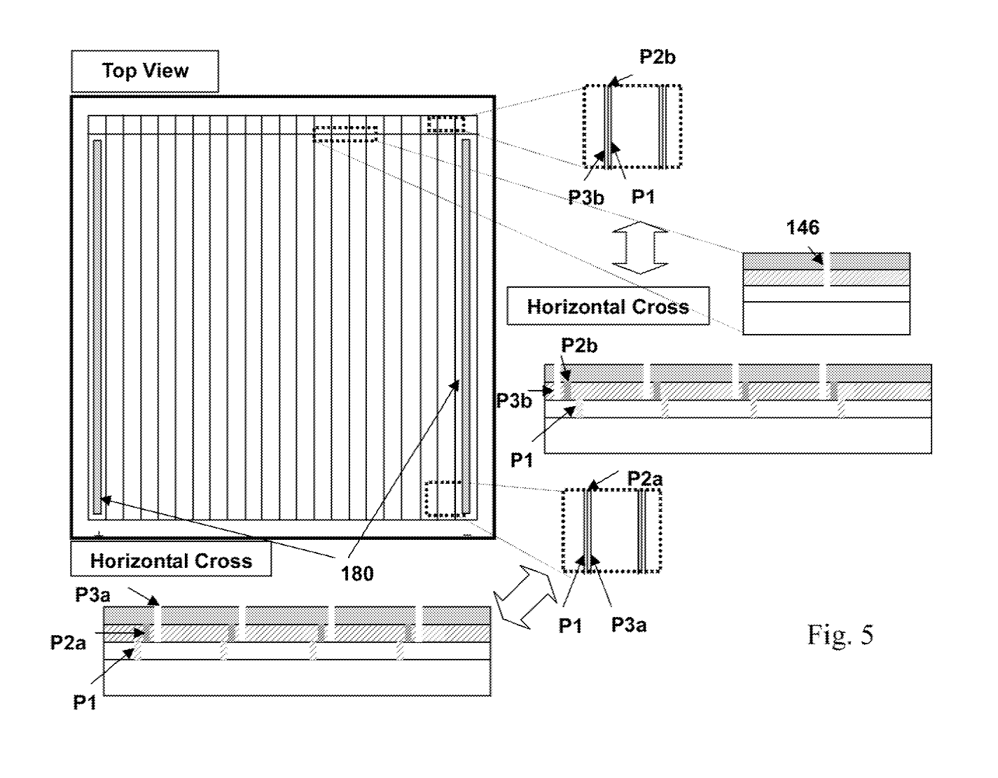

FIG. 5 is a top view and a cross view for illustrating the photovoltaic device 100 according to one or more embodiments of the present invention. As to the photovoltaic device 100, the characteristics are described as follows:

P1: removal of the front contact layer 121 (e.g., TCO layer);

P2a/P2b: removal of the layer 123 (i.e., semiconductor layer), where P2a and P2b are staggered;

P3a/P3b: removal of the layers 123 and 125 (i.e., metal & semiconductor layers), where P3a and P3b are staggered;

Moreover, ribbons 180 are disposed at two opposing sides of the photovoltaic device.

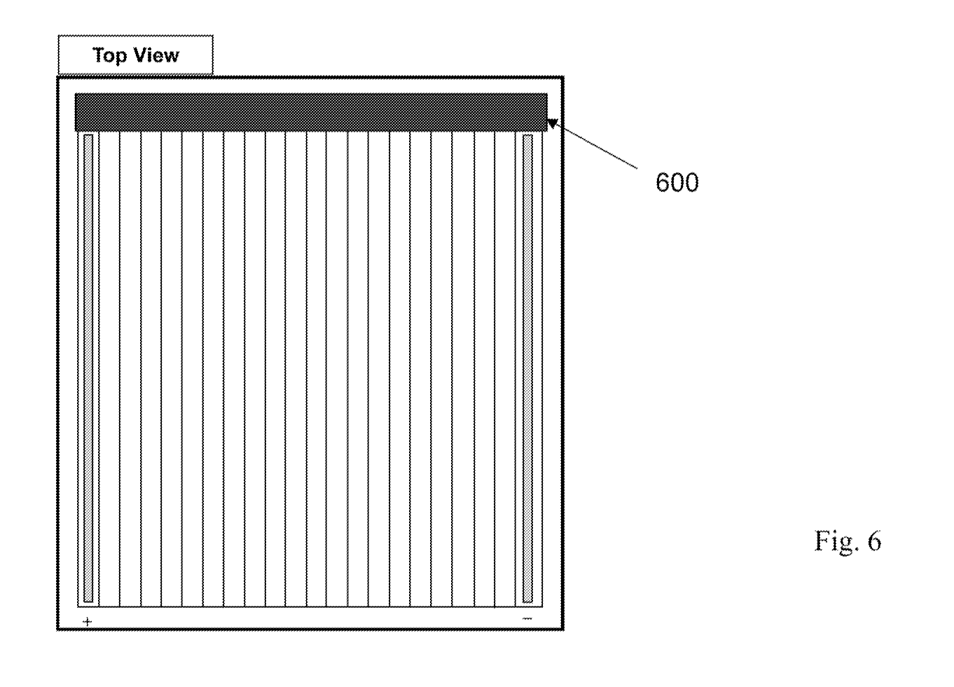

FIG. 6 shows that the bypass diodes of FIG. 5 are covered with a mask 600. When the module works, the bypass diode part will be covered with the mask to make sure that it works under dark condition.

### Experiment 1

### Reverse Current Overload of the Bypass Diode

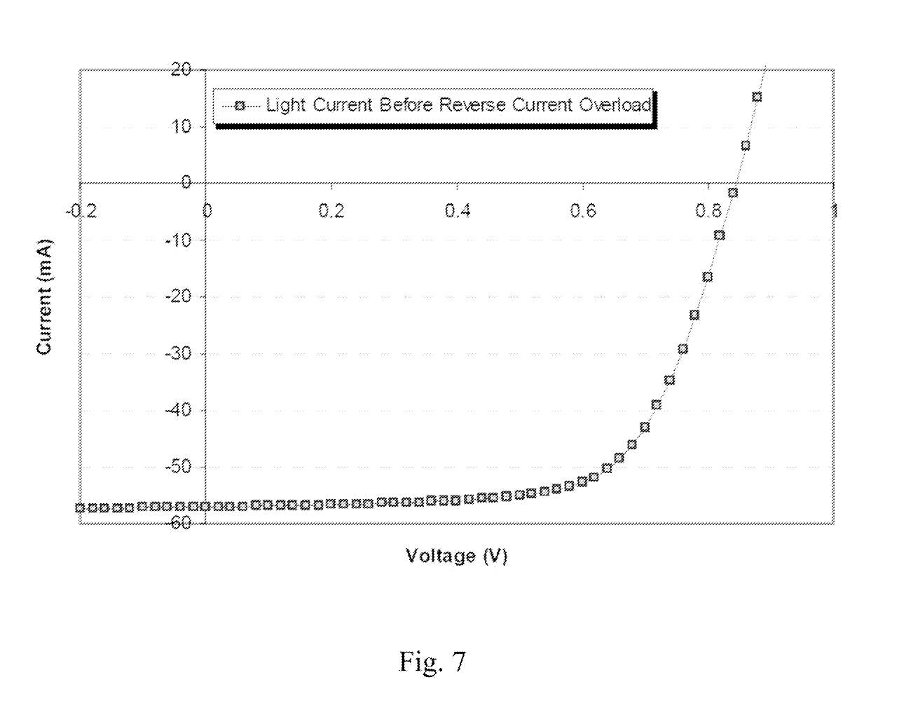

Experiment: Using a mini-sample cut from the solar cell module, measure the dark I-V curve before and after applying a constant reverse current 0.78 A (˜13×Isc) for 1 hour (See FIG. 7 for the light current under AM1.5 before the reverse current overload, where Isc ˜60 mA).

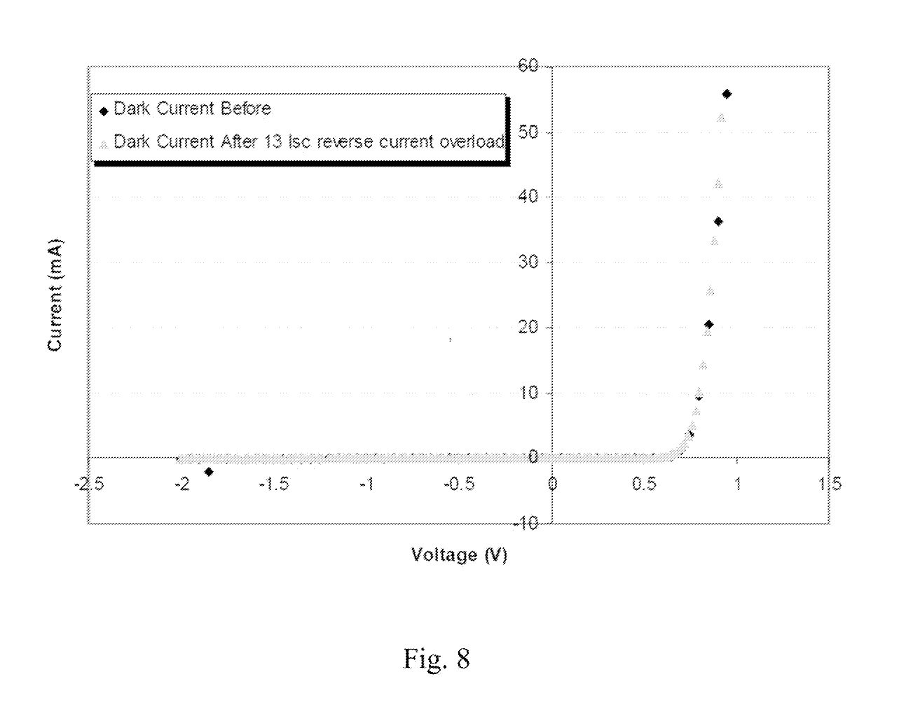

Results: The dark I-V curve after the reverse current overload experiment is consistent with the one before (see FIG. 8). This experiment result indicates that no damage will be caused to the bypass diode under the hot-spot conditions.

### Experiment 2

### Hot-Spot Endurance Test

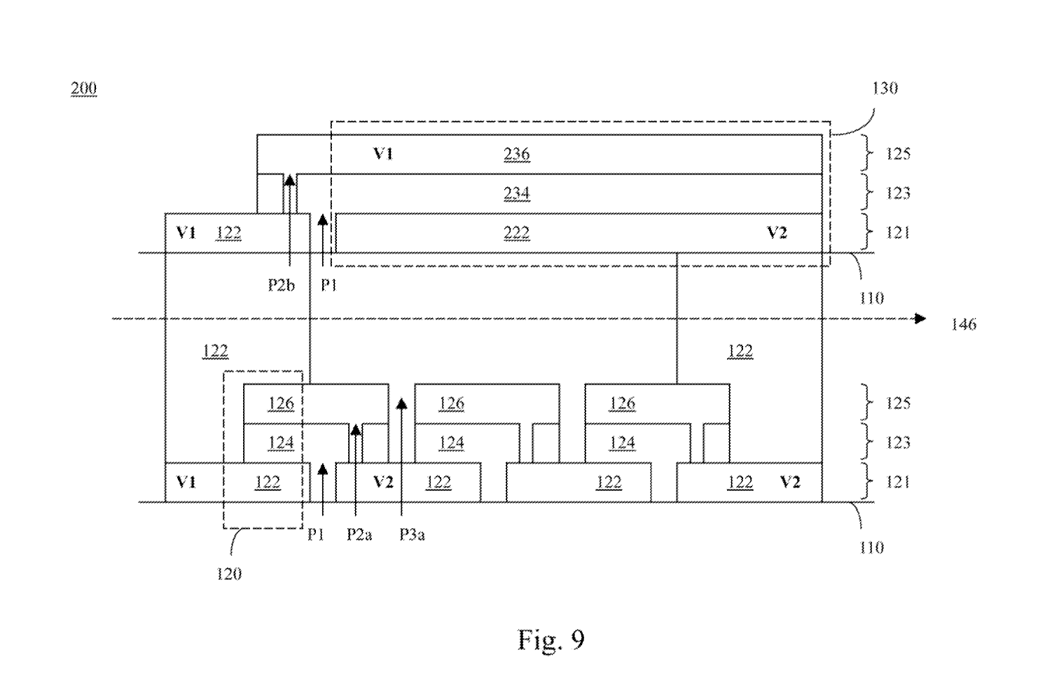

The main purpose of this invention is to eliminate hot-spot effect significantly. After hot-spot test, no visual defects can be observed and the power of the module is the same as before. In one embodiment, the highest temperature during the hot-spot test is 111.1° C., locating on the bypass diode 130 corresponding to the masked photovoltaic cells. For the photovoltaic cell part, the temperature is the same as the environment. This is as expected because when the solar cells 130 are masked, the current will flow through the bypass diodes 130 instead of the photovoltaic cells 120. In the photovoltaic device 100, each photovoltaic cell 120 has its own bypass diode 130, which is effective in eliminating hot-spot effect. FIG. 9 is a schematic diagram illustrating a photovoltaic device 200 according to one or more embodiments of the present invention. The photovoltaic device 200 is essentially the same as the photovoltaic device 100, except that the photovoltaic cells 120 share one bypass diode 130.

In the previous embodiment as in photovoltaic device 100, one bypass diode is parallel connected to one active solar cell. In the photovoltaic device 200, the bypass diode device can also be connected to several solar cells. One bypass diode 230 includes a semiconductor segment 234 of the semiconductor material formed on the first and the last of front electrode segments 122 and being parallel to the photoelectric conversion segments 124, and a second back electrode segment 236 of the metal formed on the semiconductor segment 234 and being parallel to the first back electrode segments 126. In use, the front electrode segments 122 can serve as cathodes, and the second back electrode segment 236 can serve as an anode.

The last of the front electrode segments 122 has an extension portion 222 adjacent to the first of the front electrode segment 122, the extension portion 222 is covered with the semiconductor segment 234, and the first of the front electrode segment 122 and the extension portion 222 of the last front electrode segment are separated by one of the first grooves P1.

The semiconductor segment 234 has a third groove P2b located at the first of the front electrode segments 122 when one of the second grooves P2a located at the last of the front electrode segments 122, and the third groove P2b is filled with the metal.

A group of the first back electrode segments 126 and the second back electrode segment 236 are separated by a separation groove 146 at a direction that crosses the direction of the first grooves P1. Additionally or alternatively, a group of the photoelectric conversion segments 124 and the semiconductor segment 234 are separated by the separation groove 146.

It will be understood that the above description of embodiments is given by way of example only and that those with ordinary skill in the art may make various modifications. The above specification, examples and data provide a complete description of the structure and use of exemplary embodiments of the invention. Although various embodiments of the invention have been described above with a certain degree of particularity, or with reference to one or more individual embodiments, those with ordinary skill in the art could make numerous alterations to the disclosed embodiments without departing from the spirit or scope of this invention.

Any element in a claim that does not explicitly state “means for” performing a specified function, or “step for” performing a specific function, is not to be interpreted as a “means” or “step” clause as specified in 35 U.S.C. §112, 6th paragraph. In particular, the use of “step of” in the claims herein is not intended to invoke the provisions of 35 U.S.C. §112, 6th paragraph.

What is claimed is:

1. A photovoltaic device comprising:
a transparent substrate;
a set of photovoltaic cells connected to each other in series and comprising:
a plurality of front electrode segments formed on the transparent substrate;
a plurality of photoelectric conversion segments of semiconductor material formed on the front electrode segments; and
a plurality of first back electrode segments of metal formed on the photoelectric conversion segments respectively; and
at least one bypass diode device formed on the transparent substrate and substantially equal in layer construction to each of the photovoltaic cells, wherein the bypass diode device and the photovoltaic cells share two or more of the front electrode segments.

2. The photovoltaic device of claim 1, wherein the front electrode segments are separated by first grooves, each of the photoelectric conversion segments is formed on adjacent two of front electrode segments, and the first grooves are filled with the semiconductor material.

3. The photovoltaic device of claim 2, wherein each of the photoelectric conversion segments has a second grooves located at one of the adjacent two of front electrode segments, and the second grooves are filled with the metal to form a series connection to connect the front electrode segments and the first back electrode segments.

4. The photovoltaic device of claim 3, wherein the bypass diode device includes one or a set of bypass diodes connected to each other in series and comprising:
a plurality of semiconductor segments of the semiconductor material formed on the front electrode segments and being parallel to the photoelectric conversion segments; and
a plurality of second back electrode segments of the metal formed on the semiconductor segments respectively and being parallel to the first back electrode segments.

5. The photovoltaic device of claim 4, wherein each of the semiconductor segments is formed on adjacent two of front electrode segments, each of the semiconductor segments has a third groove located at the other of the adjacent two of front electrode segments, and the third grooves are filled with the metal to form a series connection to connect the front electrode segments and the second back electrode segments.

6. The photovoltaic device of claim 5, wherein the first back electrode segments are separated by fourth grooves, and the photoelectric conversion segments are also separated by the fourth grooves.

7. The photovoltaic device of claim 6, wherein the second back electrode segments are separated by fifth grooves, and the semiconductor segments are also separated by the fifth grooves.

8. The photovoltaic device of claim 4, wherein a group of the first back electrode segments and another group of the second back electrode segments are separated by a separation groove at a direction which crosses the direction of the first grooves, and a group of the photoelectric conversion segments and another group of the semiconductor segments are separated by the separation groove.

9. The photovoltaic device of claim 3, wherein the bypass diode device includes one bypass diode comprising:
a semiconductor segment of the semiconductor material formed on the first and the last of front electrode segments and being parallel to the photoelectric conversion segments; and
a second back electrode segment of the metal formed on the semiconductor segment and being parallel to the first back electrode segments.

10. The photovoltaic device of claim 9, wherein the semiconductor segment has a third groove located at the first of the front electrode segments when one of the second grooves located at the last of the front electrode segments, and the third groove is filled with the metal.

11. The photovoltaic device of claim 10, wherein the first back electrode segments are separated by fourth grooves, and the photoelectric conversion segments are also separated by the fourth grooves.

12. The photovoltaic device of claim 9, wherein the last of front electrode segments has an extension portion adjacent to the first of the front electrode segments, the extension portion is covered with the semiconductor segment, and the first of the front electrode segment and the extension portion of the last front electrode segment are separated by one of the first grooves.

13. The photovoltaic device of claim 9, wherein a group of the first back electrode segments and another group of the second back electrode segment are separated by a separation groove at a direction which crosses the direction of the first grooves, and a group of the photoelectric conversion segments and another group of the semiconductor segment are separated by the separation groove.

14. A method of manufacturing a photovoltaic device, the method comprising:
providing a transparent substrate;
depositing a transparent conductive oxide film on a transparent substrate to form a front contact layer;
forming first grooves in the front contact layer to form front electrode segments on the transparent substrate;
depositing and forming a layer or layers of a semiconductor material on the front electrode segments, and filling the first grooves with the semiconductor material;
forming second grooves and one or more third grooves in the layer or layers of semiconductor material at positions substantially parallel to the first grooves, wherein the second and third grooves are staggered in two adjacent regions of the layer or layers of semiconductor material;
depositing and forming a back contact layer comprising a metal on the layer or layers of semiconductor material, and filling the second and third grooves with the metal to form a series connection to connect the front electrode segments and the back contact layer;
forming fourth grooves in the back contact layer and the layer or layers of semiconductor material at positions substantially parallel to the second grooves; and
forming a separation groove in the back contact layer and the layer or layers of semiconductor material at a direction which crosses the direction of the second and third grooves, so that the two adjacent regions of the layer or layers of semiconductor material are separated by the separation groove.

15. The method of claim 14, wherein the step of forming any of the grooves includes laser scribing or chemical etching any of the grooves.
